(19) United States
(12) Patent Application Publication
(10) Pub. No.: US 2013/0167928 A1
(43) Pub. Date: Jul. 4, 2013

(54) SOLAR CELL SEALING SHEET AND FLEXIBLE SOLAR CELL MODULE

(71) Applicants: Hiroshi Hiraike, Osaka (JP); Kiyomi Uenomachi, Osaka (JP); Masahiro Asuka, Osaka (JP); Jiamo Guo, Osaka (JP); Takahiro Nomura, Osaka (JP); Takahiko Sawada, Osaka (JP); Masahiro Ishii, Osaka (JP)

(72) Inventors: Hiroshi Hiraike, Osaka (JP); Kiyomi Uenomachi, Osaka (JP); Masahiro Asuka, Osaka (JP); Jiamo Guo, Osaka (JP); Takahiro Nomura, Osaka (JP); Takahiko Sawada, Osaka (JP); Masahiro Ishii, Osaka (JP)

(21) Appl. No.: 13/821,597

(22) PCT Filed: Sep. 16, 2011
(86) PCT No.: PCT/JP2011/071267

§ 371 Date: Mar. 8, 2013

(30) Foreign Application Priority Data
Oct. 6, 2010 (JP) 2010 226820
Mar. 18, 2011 (JP) 2011061594

(51) Int. Cl. H01L 31/048

(52) U.S. Cl. CPC H01L 31/0481
USPC 136/259; 428/355 R; 427/74

(57) ABSTRACT

An object of the present invention is to provide a solar cell encapsulant sheet which makes it possible to suitably produce flexible solar cell modules in which the solar cell encapsulant sheet is well adhered to a solar cell element by encapsulating a solar cell element by roll-to-roll processing in a continuous manner without the need to perform a crosslinking process and without causing wrinkles and curls. The present invention provides a solar cell encapsulant sheet including a fluoropolymer sheet and an adhesive layer that includes a maleic anhydride-modified olefin resin on the fluoropolymer sheet, the maleic anhydride-modified olefin resin being a resin in which an α-olefin-ethylene copolymer that includes 1 to 25% by weight of α-olefin units is graft-modified with maleic anhydride, and a total amount of maleic anhydride being 0.1 to 3% by weight.

### TECHNICAL FIELD

The present invention relates to: a solar cell encapsulant sheet which makes it possible to encapsulate a solar cell element in a continuous manner without the need to perform a crosslinking process and highly efficiently produce flexible solar cell modules in which the solar cell encapsulant sheet is well adhered to a solar cell element without causing wrinkles and curls; and a flexible solar cell module obtained using the solar cell encapsulant sheet.

### BACKGROUND ART

Solar cell modules known so far are: rigid solar cell modules that include a glass substrate; and flexible solar cell modules that include a thin film substrate of stainless steel or a substrate made of a heat resistant polymer material such as polyimide or polyester. In recent years, flexible solar cell modules have been attracting attention because they are easy to transport and install due to their thin and lightweight designs, and have high impact resistance.

A flexible solar cell is a laminate of a flexible solar cell element and solar cell encapsulant sheets encapsulating the upper and lower surfaces of the flexible solar cell element. The flexible solar cell element is a laminate created by stacking, on a flexible substrate, a thin layer such as a photoelectric conversion layer made of a silicon semiconductor, a compound semiconductor, or the like which generates a current when exposed to light.

The solar cell encapsulant sheets serve to mitigate impacts from the exterior and protect the solar cell element from corrosion, and consist of a transparent sheet and an adhesive layer on the transparent sheet. The adhesive layers, which are designed to encapsulate the solar cell element, have been made using ethylene-vinyl acetate (EVA) resins (for example, Patent Literature 1).

The use of EVA resins, however, has some problems such as an extended production time and generation of an acid because it requires a crosslinking process. In view of these problems, some attempts have been made to form an adhesive layer of a solar cell encapsulant sheet using a non-EVA resin such as a silane-modified olefin resin (for example, Patent Literature 2).

Flexible solar cell modules produced by encapsulation of a solar cell element with a solar cell encapsulant sheet have been conventionally produced by a method involving previously cutting a flexible solar cell element and solar cell encapsulant sheets into desired shapes, stacking the cut pieces, and bonding them together into an integrated laminate in a static state by vacuum laminating. Such vacuum laminating methods take a long time to finish bonding, and therefore are disadvantageously less efficient in producing solar cell modules.

One of the methods for producing a flexible solar cell module under study is roll-to-roll processing that is advantageous for mass production (for example, Patent Literature 3).

The roll-to-roll processing is a technique to produce a flexible solar cell module in a continuous manner, and uses a roll of a solar cell encapsulant film sheet. The solar cell encapsulant sheet is unrolled, and subjected to thermocompression bonding in which the solar cell encapsulant sheet is pressed together with a solar cell element between a pair of rolls to encapsulate the solar cell element.

The roll-to-roll processing is expected to enable continuous and remarkably efficient production of flexible solar cell modules.

However, the roll-to-roll processing, when used to produce a flexible solar cell module by encapsulating a flexible solar cell element with a conventional solar cell encapsulant sheet, causes some problems that strikingly reduce the production efficiency, such as the need to perform a crosslinking process and occurrence of wrinkles and curls upon thermocompression bonding of the flexible solar cell element and the solar cell encapsulant sheet between rolls, and other problems such as insufficient adhesion between the flexible solar cell element and the solar cell encapsulant sheet.

In this context, there has been a demand for development of a solar cell encapsulant sheet that maintains the high production efficiency of the roll-to-roll processing enough, prevents wrinkles and curls, and allows a flexible solar cell element to be well encapsulated in a continuous manner.

### CITATION LIST

### Patent Literature

Patent Literature 1: Japanese Kokai Publication No. Hei-07-297439 (JP-A H07-297439)
Patent Literature 2: Japanese Kokai Publication No. 2004-214641 (JP-A 2004-214641)
Patent Literature 3: Japanese Kokai Publication No. 2000-294815 (JP-A 2000-294815)

### SUMMARY OF INVENTION

### Technical Problem

In view of the above-mentioned situation, the present invention aims to provide: a solar cell encapsulant sheet which makes it possible to encapsulate a solar cell element in a continuous manner without the need to perform a crosslinking process and highly efficiently produce flexible solar cell modules in which the solar cell encapsulant sheet is well adhered to a solar cell element without causing wrinkles and curls; and a flexible solar cell module obtained using the solar cell encapsulant sheet.

### Solution to Problem

The present invention provides a solar cell encapsulant sheet including a fluoropolymer sheet and an adhesive layer that includes a maleic anhydride-modified olefin resin on the fluoropolymer sheet, the maleic anhydride-modified olefin resin being a resin in which an α-olefin-ethylene copolymer that includes 1 to 25% by weight of α-olefin units is graft-modified with maleic anhydride, and a total amount of maleic anhydride being 0.1 to 3% by weight.

The present invention will be illustrated in the following.

The present invention provides a solar cell encapsulant sheet that includes an adhesive layer containing specific ingredients and a fluoropolymer sheet and makes it possible to produce flexible solar cell modules in which the solar cell encapsulant sheet is well adhered to a solar cell element and no wrinkles and curls appear by roll-to-roll processing.

Specifically, the present inventors found that a solar cell encapsulant sheet which includes an adhesive layer containing a specific resin on a fluoropolymer sheet enables thermocompression bonding at a relatively low temperature in a relatively short time without the need of crosslinking processing, which makes it possible to produce flexible solar cell modules without wrinkles and curls even when solar cell elements are encapsulated in a continuous manner by roll-to-roll processing. The present invention was thus completed.

The solar cell encapsulant sheet of the present invention includes a fluoropolymer sheet and an adhesive layer which contains a maleic anhydride-modified olefin resin on the fluoropolymer sheet.

FIG. 1 is a vertical cross-sectional view schematically showing one example of a solar cell encapsulant sheet A of the present invention, containing a fluoropolymer sheet 1 and an adhesive layer 2.

The maleic anhydride-modified olefin resin is a resin in which an α-olefin-ethylene copolymer is graft-modified with maleic anhydride.

Since the solar cell encapsulant sheet of the present invention includes an adhesive layer containing such a specific resin, preferable encapsulation of solar cell elements by roll-to-roll processing is possible with excellent adhesion and no wrinkles and curls.

The α-olefin preferably has 3 to 10 carbon atoms, and more preferably 4 to 8 carbon atoms in order for the resin to be more amorphous, and in turn, have a low melting point and improved flexibility.

Specific examples of the α-olefin include propylene, 1-butene, 1-pentene, 1-hexene, 1-heptene, and 1-octene. In particular, preferable are 1-butene, 1-hexene, and 1-octene.

The α-olefin-ethylene copolymer is preferably a butene-ethylene copolymer, a hexene-ethylene copolymer, or an octene-ethylene copolymer.

The α-olefin-ethylene copolymer contains 1 to 25% by weight of α-olefin units. If the amount of α-olefin units is less than 1% by weight, the melting point of the solar cell encapsulant sheet increases as the flexibility of the solar cell encapsulant sheet decreases. Thereby, the solar cell element needs to be encapsulated under high-temperature heating. As a result, wrinkles and curls tend to occur upon production of flexible solar cell modules. If the amount of α-olefin units is more than 25% by weight, the solar cell encapsulant sheet does not have a uniform crystallizability/fluidity, leading to deformation of the solar cell encapsulant sheet. In addition, the melting point of the solar cell encapsulant sheet itself is too low, whereby the sheet has difficulty in maintaining its shape when the solar cell element is exposed to high temperature environments. As a result, the solar cell encapsulant sheet may have less adhesion to the solar cell element and may be deformed. The lower limit of the amount of α-olefin units is preferably 10% by weight, and the upper limit thereof is preferably 20% by weight.

The amount of the α-olefin units in the α-olefin-ethylene copolymer may be determined from the integration value of ¹³C-NMR spectrum. Specifically, in the case that 1-butene is used, the amount of the α-olefin units is determined by calculation using spectrum integration values of 1-butene spectra at around 10.9 ppm, 26.1 ppm, and 39.1 ppm and spectrum integration values of ethylene spectra at around 26.9 ppm, 29.7 ppm, 30.2 ppm, and 33.4 ppm, which are obtained by measuring the copolymer in deuterated chloroform. The spectral assignments may be determined using known data such as Koubunshi Bunseki Handobukku (Handbook of Polymer Analysis, edited by The Japan Society for Analytical Chemistry, published by Asakura Publishing Co., Ltd. in 2008).

Any known method may be used for graft modification of the α-olefin-ethylene copolymer with maleic anhydride, and examples thereof include: melt modification method which is a method of providing a composition containing the α-olefin-ethylene copolymer, maleic anhydride, and a radical polymerization initiator in an extruder and then melt-kneading the composition to initiate graft polymerization of maleic anhydride to the copolymer; and solution modification method which is a method of dissolving the α-olefin-ethylene copolymer in a solvent to prepare a solution and then adding maleic anhydride and a radical polymerization initiator to the solution for graft polymerization of maleic anhydride to the copolymer. Among these methods, the melt modification method is preferable because the ingredients can be mixed in an extruder and high productivity is achieved.

The radical polymerization initiator used in the method for graft modification is not particularly limited, provided that it is conventionally used for radical polymerization. Specific examples thereof include benzoyl peroxide, cumene hydroperoxide, diisopropyl peroxydicarbonate, cumyl peroxyneodecanoate, cumyl peroxyoctoate, and azobisisobutyronitrile.

The maleic anhydride-modified olefin resin includes 0.1 to 3% by weight of maleic anhydride in total. If the total amount of maleic anhydride is less than 0.1% by weight, the adhesion of the solar cell encapsulant sheet to the solar cell element is reduced. If the total amount of maleic anhydride is more than 3% by weight, the maleic anhydride-modified olefin resin is crosslinked into a gel upon production of the solar cell encapsulant sheet, which inhibits the production of the solar cell encapsulant sheet or decreases the extrusion moldability of the solar cell encapsulant sheet. The lower limit of the total amount of maleic anhydride is preferably 0.2% by weight, and the upper limit is preferably 1.5% by weight. The total amount of maleic anhydride is more preferably less than 1.0% by weight.

The total amount of maleic anhydride can be calculated by preparing a test film using the maleic anhydride-modified olefin resin and measuring the infrared absorption spectrum of the test film to determine the absorption intensity near 1790 cm⁻¹. More specifically, the total amount of maleic anhydride in the maleic anhydride-modified olefin resin is, for example, determined by a known method disclosed in Koubunshi Bunseki Handobukku (Handbook of Polymer Analysis, edited by The Japan Society for Analytical Chemistry, published by Asakura Publishing Co., Ltd. in 2008) or the like using FT-IR (Nicolet 6700 FT-IR, a fourier transform infrared spectrometer).

The maleic anhydride-modified olefin resin preferably has a maximum peak temperature (Tm) of 80 to 125° C. which is determined from an endothermic curve obtained by differential scanning calorimetry. If the maximum peak temperature (Tm) determined from an endothermic curve is lower than 80° C., the solar cell encapsulant sheet may be less heat resistant. If the maximum peak temperature (Tm) determined from an endothermic curve is higher than 125° C., the solar cell encapsulant sheet may require a longer period of heating in the encapsulation process, leading to lower production efficiency of flexible solar cell modules or failing to sufficiently encapsulate the solar cell element. The maximum peak temperature (Tm) of an endothermic curve is more preferably 83 to 110° C.

The maximum peak temperature (Tm) of an endothermic curve obtained by differential scanning calorimetry is measured in accordance with the method specified in JIS K7121.

The maleic anhydride-modified olefin resin preferably has a melt flow rate (MFR) of 0.5 to 29 g/10 min. If the melt flow rate is less than 0.5 g/10 min, uneven portions may be formed on the solar cell encapsulant sheet in the process of forming the encapsulant sheet, resulting in production of a flexible solar cell module that tends to curl. If the melt flow rate is more than 29 g/10 min, the possibility of drawdown in the process of forming the solar cell encapsulant sheet is high, in other words, it is difficult to form a sheet with an even thickness. This case may also result in production of a flexible solar cell module that tends to curl, formation of pinholes or the like in the solar cell encapsulant sheet, or loss of insulation properties of the entire solar cell module. The melt flow rate is more preferably 2 g/10 min to 10 g/10 min.

The melt flow rate of the maleic anhydride-modified olefin resin is measured under a load of 2.16 kg in accordance with ASTM D1238 which is used to measure the melt flow rate of polyethylene resins.

The maleic anhydride-modified olefin resin preferably has a viscoelastic storage modulus at 30° C. of not more than 2×10⁸ Pa. If the viscoelastic storage modulus at 30° C. is more than 2×10⁸ Pa, the solar cell encapsulant sheet may be less flexible, and therefore may be difficult to handle. Additionally, rapid heating of the solar cell encapsulant sheet may be required to encapsulate the solar cell element with the solar cell encapsulant sheet in the process of producing a solar cell module. If the viscoelastic storage modulus at 30° C. is too low, the solar cell encapsulant sheet may become sticky at room temperature, and therefore may be difficult to handle. Accordingly, the lower limit thereof is preferably 1×10⁷ Pa. The upper limit is more preferably 1.5×10⁸ Pa.

The maleic anhydride-modified olefin resin preferably has a viscoelastic storage modulus at 100° C. of not more than 5×10⁶ Pa. If the viscoelastic storage modulus at 100° C. is more than 5×10⁶ Pa, the adhesion of the solar cell encapsulant sheet to the solar cell element may be weak. If the viscoelastic storage modulus at 100° C. is too low, the solar cell encapsulant sheet may significantly flow when pressing force is applied to encapsulate the solar cell element with the solar cell encapsulant sheet in the process of producing a solar cell module. In this case, the thickness of the solar cell encapsulant sheet may become significantly uneven. Accordingly, the lower limit thereof is preferably 1×10⁴ Pa. The upper limit is more preferably 4×10⁶ Pa.

The viscoelastic storage modulus of the maleic anhydride-modified olefin resin is measured by a testing method for dynamic properties in accordance with JIS K6394.

The adhesive layer preferably further contains a silane compound. The presence of a silane compound further improves the adhesion between the adhesive layer and the surface of the solar cell element.

Particularly, the adhesive layer preferably includes an epoxy group-containing silane compound. The epoxy group-containing silane compound especially enhances the heat resistance of a resulting flexible solar cell module while high productivity by roll-to-roll processing is sufficiently achieved. Additionally, even when the solar cell encapsulant sheet has an already embossed surface, it is more likely to avoid loss of the embossed pattern in thermocompression bonding to a solar cell element.

When the epoxy group-containing silane compound is added, a maleic anhydride group in the maleic anhydride-modified olefin resin reacts with an epoxy group of the epoxy group-containing silane compound, so that the silane compound is introduced into a side chain of the resin. Moreover, the silane compound molecules in the side chains form a siloxane bond by hydrolytic condensation to form crosslinks in the resin. In other words, the epoxy group-containing silane compound also serves as a crosslinking agent of the maleic anhydride-modified olefin resin. The formation of crosslinks in the resin presumably improves the modulus of elasticity at elevated temperatures, whereby the heat resistance increases.

The epoxy group-containing silane compound may contain at least one epoxy group such as an aliphatic epoxy group or an alicyclic epoxy group in a molecule. The epoxy group-containing silane compound is preferably a silane compound represented by the formula (I).

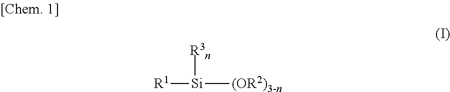

In the formula, R¹ is 3-glycidoxypropyl or 2-(3,4-epoxycyclohexyl)ethyl, R² is an alkyl group containing 1 to 3 carbon atoms, R³ is an alkyl group containing 1 to 3 carbon atoms, and n is 0 or 1.

R¹ is 3-glycidoxypropyl of the formula (II) or 2-(3,4-epoxycyclohexyl)ethyl of the formula (III).

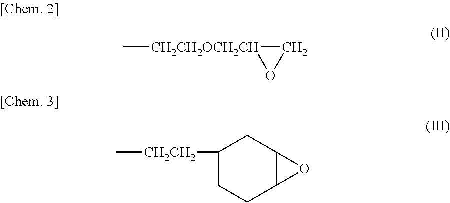

R² is not particularly limited, provided that it is an alkyl group containing 1 to 3 carbon atoms. Examples thereof include methyl, ethyl, and propyl. Preferred are methyl and ethyl, and methyl is more preferred.

R³ is not particularly limited, provided that it is an alkyl group containing 1 to 3 carbon atoms. Examples thereof include methyl, ethyl, and propyl. Preferred is methyl.

In the formula (I), n is 0 or 1, and preferably 0.

Examples of the silane compound represented by the formula (I) include 3-glycidoxypropylmethyldimethoxysilane, 3-glycidoxypropylmethyldiethoxysilane, 3-glycidoxypropyltrimethoxysilane, 3-glycidoxypropyltriethoxysilane, 3-glycidoxypropyltripropoxysilane, 2-(3,4-epoxycyclohexyl)ethyltrimethoxysilane, 2-(3,4-epoxycyclohexyl)ethyltriethoxysilane, and 2-(3,4-epoxycyclohexyl)ethyltripropoxysilane. Preferred are 3-glycidoxypropyltrimethoxysilane, 2-(3,4-epoxycyclohexyl)ethyltrimethoxysilane), 3-glycidoxypropyltriethoxysilane, 3-glycidoxypropylmethyldimethoxysilane, and 3-glycidoxypropylmethyldiethoxysilane.

Examples of commercial products of the silane compound represented by the formula (I) include Z-6040 (3-glycidoxypropyltrimethoxysilane), Z-6043 (2-(3,4-epoxycyclohexyl)ethyltrimethoxysilane), available from Dow Corning Toray Co., Ltd., KBE-403 (3-glycidoxypropyltriethoxysilane), KBM-402 (3-glycidoxypropylmethyldimethoxysilane), and KBE-402 (3-glycidoxypropylmethyldiethoxysilane), available from Shin-Etsu Chemical Co., Ltd.

The silane compound content in the adhesive layer is preferably 0.05 to 5 parts by weight relative to 100 parts by weight of the maleic anhydride-modified olefin resin. If the silane compound content is less than 0.05 parts by weight, the adhesion of the solar cell encapsulant sheet may be reduced. If the silane compound content is more than 5 parts by weight, the solar cell encapsulant sheet may strongly contract, resulting in generation of wrinkles and gelation, which deteriorates the appearance of the sheet. The lower limit of the silane compound content is more preferably 0.1 parts by weight, and the upper limit thereof is more preferably 1.5 parts by weight.

When the adhesive layer contains the epoxy group-containing silane compound, the viscosity of the resin for the adhesive layer increases because of the crosslinking reaction of the maleic anhydride-modified olefin resin, resulting in poor handling ability in extrusion molding. In such a case a low-density polyethylene is preferably contained in the adhesive layer. Use of a low-density polyethylene improves the handling ability while maintaining various properties such as adhesion.

The low-density polyethylene may be a linear low-density polyethylene, and more specifically, a copolymer of ethylene and α-olefin.

The adhesive layer may further contain other additives such as photostabilizers, ultraviolet absorbers, and heat stabilizers in amounts that do not impair the physical properties of the adhesive layer.

Examples of the method for forming the adhesive layer include a method that involves melting predetermined ratios (weight basis) of the maleic anhydride-modified olefin resin and the silane compound, and optionally predetermined ratios (weight basis) of additives in an extruder, kneading the mixture, and extruding the mixture into a sheet from the extruder.

The thickness of the adhesive layer is preferably 80 to 700 μm. If the thickness of the adhesive layer is less than 80 μm, the adhesive layer may fail to ensure the insulation properties of flexible solar cell modules. If the thickness of the adhesive layer is more than 700 μm, flexible solar cell modules with impaired flame retardancy or heavy flexible solar cell modules may be provided. Additionally, it is disadvantageous for cost reasons. The lower limit of the thickness of the adhesive layer is preferably 150 μm, and the upper limit thereof is preferably 400 μm.

The adhesive layer is, for example, formed by a method of providing a raw composition for the adhesive layer in an extruder, melt-kneading the composition, and extruding the composition into a sheet from the extruder. In particular, if the adhesive layer contains the epoxy group-containing silane compound, the reaction between a maleic anhydride group in the maleic anhydride-modified olefin resin and an epoxy group in the epoxy group-containing silane compound proceeds during the melt-kneading in and extruding from the extruder. Furthermore, the silane compound molecules in the side chains of the resin form a siloxane bond by hydrolytic condensation to form crosslinks in the resin. Thereby, the modulus of elasticity of the adhesive layer at elevated temperatures is improved, which effectively increases the heat resistance.

The method for producing a solar cell encapsulant sheet, which includes forming an adhesive layer by charging an extruder with the following components:
100 parts by weight of a maleic anhydride-modified olefin resin, the maleic anhydride-modified olefin resin being a resin in which an α-olefin-ethylene copolymer that includes 1 to 25% by weight of α-olefin units is graft-modified with maleic anhydride, and a total amount of maleic anhydride being 0.1 to 3% by weight; and
0.05 to 5 parts by weight of a silane compound represented by the formula (I),

and melt-kneading and extruding the components from the extruder to form an adhesive layer in a sheet form, is another aspect of the present invention.

In the solar cell encapsulant sheet, the adhesive layer is formed on a fluoropolymer sheet.

The fluoropolymer sheet is not particularly limited, provided that it is excellent in transparency, heat resistance, and flame retardancy. Preferably, the fluoropolymer sheet includes at least one fluoropolymer selected from the group consisting of a tetrafluoroethylene-ethylene copolymer (ETFE), an ethylene-chlorotrifluoroethylene resin (ECTFE), a polychlorotrifluoroethylene resin (PCTFE), a polyvinylidene fluoride resin (PVDF), a tetrafluoroethylene-perfluoroalkyl vinyl ether copolymer (FAP), a polyvinyl fluoride resin (PVF), a tetrafluoroethylene-hexafluoropropylene copolymer (FEP), a vinylidene fluoride-hexafluoropropylene copolymer (PVDF-HFP), and a mixture of polyvinylidene fluoride and polymethylmethacrylate (PVDF/PMMA).

In particular, the fluoropolymer is more preferably selected from a polyvinylidene fluoride resin (PVDF), a tetrafluoroethylene-ethylene copolymer (ETFE), or a polyvinyl fluoride resin (PVF), because of their better heat resistance and transparency.

The thickness of the fluoropolymer sheet is preferably 10 to 100 μm. If the thickness of the fluoropolymer sheet is less than 10 μm, the fluoropolymer sheet may fail to ensure the insulation properties, and may impair the flame retardancy. If the thickness of the fluoropolymer sheet is more than 100 μm, heavy flexible solar cell modules may be provided, which is disadvantageous for cost reasons. The lower limit of the thickness of the fluoropolymer sheet is preferably 15 μm, and the upper limit thereof is preferably 80 μm.

The solar cell encapsulant sheet can be formed by integrating the fluoropolymer sheet and the adhesive layer into a laminate. The integration into a laminate can be accomplished by any methods, and examples of integration methods include a method in which the fluoropolymer sheet is formed on one surface of the adhesive layer by extrusion lamination, and a method in which the adhesive layer and the fluoropolymer sheet are formed by coextrusion. In particular, it is preferable to simultaneously form the sheet and the layer as a laminate by coextrusion.

The extrusion temperature in the coextrusion process is preferably higher than the melting point of the fluoropolymer and the maleic anhydride-modified olefin resin by 30° C. or more and is preferably lower than the decomposition temperature thereof by 30° C. or more.

As described above, the solar cell encapsulant sheet is preferably an integrated laminate formed by simultaneously forming the adhesive layer and the fluoropolymer sheet by coextrusion.

The method for producing a solar cell encapsulant sheet, by simultaneously extruding a resin composition that includes the maleic anhydride-modified olefin resin and optional additives such as an epoxy group-containing silane compound, and the fluoropolymer into sheets by coextrusion, thereby forming a laminate, is another aspect of the present invention.

The solar cell encapsulant sheet preferably has an embossed surface. In particular, a surface of the solar cell encapsulant sheet which is to be a light-receiving surface in use is preferably embossed. More specifically, a surface of the fluoropolymer sheet of the solar cell encapsulant sheet which is to be a light-receiving surface of a produced flexible solar cell module is preferably embossed.

The embossed pattern reduces the reflection loss of sunlight, prevents glare, and improves the appearance.

The embossed pattern may consist of peaks and valleys arranged in a regular pattern or peaks and valleys arranged in a random fashion.

The embossed pattern may be formed before, after, or at the same time as adhering the solar cell encapsulant sheet to the solar cell element.

Particularly, the embossed pattern is preferably formed before adhering to the solar cell element in order to prevent the surface from being non-uniformly embossed and provide a uniformly embossed pattern.

Especially, the embossed pattern is more preferably formed at the same time as cooling the molten resin using an emboss roll as a chill roll during simultaneous formation of the adhesive layer and the fluoropolymer sheet of the solar cell encapsulant sheet by coextrusion in order to prevent deformation of the embossed pattern in the process of adhering to the solar cell element and ensure a uniformly embossed pattern.

In the case that a conventional solar cell encapsulant sheet with an already embossed surface is used, part of the embossed pattern may be lost during the thermocompression bonding process for encapsulating the flexible solar cell element. For this reason, a common strategy used against conventional solar cell encapsulant sheets is to emboss the surface separately after encapsulating the flexible solar cell element.

In contrast, the solar cell encapsulant sheet of the present invention can preserve the embossed pattern even through the thermocompression bonding process. This is presumably because the adhesive layer has a sufficiently high viscoelastic storage modulus as well as sufficient adhesion strength. Therefore, in the case of the solar cell encapsulant sheet of the present invention, previous embossment on the surface enables to avoid a troublesome process of additional embossment on the surface after the encapsulation process by roll-to-roll processing or the like. The effects from this particularly work well when the adhesive layer contains the epoxy group-containing silane compound.

The solar cell encapsulant sheet of the present invention is used for encapsulating a solar cell element to produce flexible solar cell modules.

The solar cell element commonly includes a photoelectric conversion layer that generates electrons when receiving light, an electrode layer that draws generated electrons, and a flexible substrate.

FIG. 2 is a vertical cross-sectional view schematically showing one example of a solar cell B including a photoelectric conversion layer 3 on a flexible substrate 4. It should be noted that electrode layers are omitted because many variations of arrangements thereof are possible.

The photoelectric conversion layer may be made of, for example, a crystalline semiconductor (e.g. monocrystal silicon, monocrystal germanium, polycrystal silicon, microcrystal silicon), an amorphous semiconductor (e.g. amorphous silicon), a compound semiconductor (e.g. GaAs, InP, AlGaAs, Cds, CdTe, Cu₂S, CuInSe₂, CuInS₂), or an organic semiconductor (e.g. phthalocyanine, polyacetylene).

The photoelectric conversion layer may be a monolayer or a multilayer.

The thickness of the photoelectric conversion layer is preferably 0.5 to 10 μm.

The flexible substrate is not particularly limited, provided that it is flexible and suited for flexible solar cells. Examples thereof include substrates made of a heat resistant resin such as polyimide, polyether ether ketone, or polyethersulfone.

The thickness of the flexible substrate is preferably 10 to 80 μm.

The electrode layer is a layer made of an electrode material.

The electrode layer may be formed on the photoelectric conversion layer, between the photoelectric conversion layer and the flexible substrate, or on the flexible substrate, according to need.

The solar cell element may have two or more electrode layers.

The electrode layer is preferably a transparent electrode when located on the light-receiving surface side because it is required to allow light to pass through. The electrode material is not particularly limited, provided that it is a common transparent electrode material such as a metal oxide. Preferred examples thereof include ITO and ZnO.

In the case that it is not a transparent electrode, it may be a metal (e.g. silver) patterned bus electrode or a metal (e.g. silver) patterned finger electrode, which is used with a bus electrode.

In the case that the electrode layer is located on the back side, it is not necessarily transparent and may be made of a common electrode material. The electrode material, however, is preferably silver.

The solar cell element is produced by any common methods, and examples thereof include a known method in which the photoelectric conversion layer and electrode layers are stacked on the flexible substrate.

The solar cell element may be a long sheet wound into a roll or a rectangular sheet.

Examples of the method for producing a flexible solar cell module by encapsulating the solar cell element with the solar cell encapsulant sheet of the present invention include a method of thermocompression bonding the solar cell encapsulant sheet to at least the light-receiving surface of the solar cell element by pressing the solar cell encapsulant sheet and the solar cell element between a pair of heating rolls.

The light-receiving surface of the solar cell element is a surface that generates electric power from received light, and refers to the photoelectric conversion layer-side surface and not to the flexible substrate-side surface.

In the method for producing a flexible solar cell module, the thermocompression bonding is preferably accomplished by stacking the solar cell element and the solar cell encapsulant sheet such that the photoelectric conversion layer-side surface of the solar cell element faces the surface of the adhesive layer of the solar cell encapsulant sheet of the present invention, and pressing them by a pair of heating rolls.

The temperature of the heating rolls used in the pressing process is preferably 70 to 160° C. If the heating roll temperature is lower than 70° C., adhesion failure may occur. If the heating roll temperature is higher than 160° C., wrinkles are likely to occur by the thermocompression bonding. The more preferable heating roll temperature is 80 to 150° C.

The rotation speed of the heating rolls is preferably 0.1 to 10 m/min. If the rotation speed of the heating rolls is less than 0.1 m/min, wrinkles are likely to occur after the thermocompression bonding. If the rotation speed of the heating rolls is more than 10 m/min, adhesion failure may occur. The rotation speed of the heating rolls is more preferably 0.3 to 5 m/min.

The following description is offered to specifically illustrate one example of the method for producing a flexible solar cell module using the solar cell encapsulant sheet of the present invention with referring to FIG. 3.

As shown in FIG. 3, a solar cell encapsulant sheet A and a solar cell element B are both long sheets wound into a roll. First, the solar cell encapsulant sheet A and the solar cell element B are unrolled such that the light-receiving surface of the solar cell element B faces the adhesive layer surface of the solar cell encapsulant sheet A, and stacked to form a laminate sheet C.

Subsequently, a laminate sheet C is inserted between a pair of rolls D and D that are heated to a predetermined temperature, and the solar cell element B and the solar cell encapsulant sheet A are adhered to and integrated with each other by thermocompression bonding in which the laminate sheet C is heated and pressed in the thickness direction. Consequently, the solar cell element is encapsulated with the solar cell encapsulant sheet, thereby providing a flexible solar cell module E.

Examples of the method for producing a flexible solar cell module using the solar cell encapsulant sheet of the present invention also include a method of cutting the solar cell encapsulant sheet(s) of the present invention and a solar cell element into desired shapes, stacking the solar cell encapsulant sheet(s) and the solar cell element such that the adhesive layer of the solar cell encapsulant sheet faces the photoelectric conversion layer-side surface of the solar cell element, or such that the adhesive layers of the solar cell encapsulant sheets face the respective surfaces of the solar cell element, thereby producing a laminate, and heating and pressing the laminate with force in the thickness direction in a static state under reduced pressure, thereby encapsulating the solar cell element with the solar cell encapsulant sheet.

The process of heating and pressing the laminate with force in the thickness direction under reduced pressure may be performed with a known device such as a vacuum laminator.

FIG. 4 is a vertical cross-sectional view schematically showing an exemplary flexible solar cell module produced using the solar cell encapsulant sheet of the present invention.

The photoelectric conversion layer 3-side surface of the solar cell element B is encapsulated with the adhesive layer 2 of the solar cell encapsulant sheet A, as shown in FIG. 4, so that the flexible solar cell module E, an integrated laminate of the solar cell encapsulant sheet A and the solar cell element B, is obtained.

Such a flexible solar cell module is also another aspect of the present invention.

Examples of the flexible solar cell module produced using the solar cell encapsulant sheet of the present invention include an integrated laminate including a first solar cell encapsulant sheet of the present invention, the solar cell element, and a second solar cell encapsulant sheet of the present invention in this order. FIG. 5 is a vertical cross-sectional view schematically showing one example of a flexible solar cell module having such a structure.

A flexible solar cell module F shown in FIG. 5 has a structure where the photoelectric conversion layer 3-side surface and the flexible substrate 4-side surface of the solar cell element B are both encapsuled with the adhesive layers 2 of the solar cell encapsulant sheets A.

Another example of the flexible solar cell module is an integrated laminate including the solar cell encapsulant sheet of the present invention, the solar cell element, an adhesive layer including a maleic anhydride-modified olefin resin, and a metal plate in this order. FIG. 6 is a vertical cross-sectional view schematically showing one example of a flexible solar cell module having such a structure. In the case that the flexible substrate-side surface of the solar cell element is encapsulated, a metal plate may be used because light transmitting properties are not required.

Examples of the adhesive layer including a maleic anhydride-modified olefin resin include the same adhesive layers as those described above for the solar cell encapsulant sheet of the present invention.

Examples of the metal plate include plates of stainless steel and plates of aluminum.

The thickness of the metal plate is preferably 25 to 800 μm.

As described, when the flexible substrate-side surface (back surface) of the solar cell element is encapsulated as well as the photoelectric conversion layer-side surface (front surface), the solar cell element is encapsulated more favorably. In this case, the resulting flexible solar cell module can stably generate electric power for a longer time.

Such a flexible solar cell module produced using the solar cell encapsulant sheet of the present invention is also another aspect of the present invention.

The flexible substrate-side surface (back surface) can be encapsulated, for example, according to the above described method of stacking the solar cell encapsulant sheet of the present invention on the flexible substrate-side surface (back surface) of the solar cell element such that the adhesive layer faces the flexible substrate, and then thermocompression bonding them between a pair of heating rolls.

In the case that the flexible substrate-side surface (back surface) of the solar cell element is encapsulated with the adhesive layer and the metal plate, the encapsulation can be accomplished by, for example, forming a sheet of the adhesive layer and the metal plate, and thermocompression bonding of the sheet of the adhesive layer and the metal plate to the flexible substrate-side surface (back surface) of the solar cell element, that is, thermocompression bonding of the flexible substrate and the adhesive layer in the manner described above.

The thermocompression bonding process of the solar cell encapsulant sheet or the sheet of the adhesive layer and the metal plate to the flexible substrate-side surface (back surface) of the solar cell element may be carried out before, after, or at the same time as the above-described thermocompression bonding process of the solar cell encapsulant sheet to the light-receiving surface of the solar cell element.

The following description is offered to illustrate, using FIG. 7, one example of the method for simultaneously encapsulating the photoelectric conversion layer-side surface (front surface) and the flexible substrate-side surface (back surface) of a solar cell element using the solar cell encapsulant sheet of the present invention.

Specifically, in addition to a long solar cell element B wound into a roll, two long solar cell encapsulant sheets wound into rolls are prepared. As shown in FIG. 7, the long solar cell encapsulant sheets A and A are unrolled while the long solar cell element B is also unrolled. The solar cell encapsulant sheets A and A are set such that the adhesive layers of the two sheets face each other, and stacked with the solar cell element B sandwiched therebetween to form a laminate sheet C. The laminate sheet C is inserted between a pair of rolls D and D that are heated to a predetermined temperature, and the solar cell encapsulant sheets A and A are adhered to and integrated with each other by heating and pressing the laminate sheet C in the thickness direction so that the solar cell element B is encapsulated between the solar cell encapsulant sheets A and A. In this manner, a solar cell module F is formed in a continuous manner.

The pressing of the laminate sheet C in the thickness direction under heating may be performed at the same time as the formation of the laminate sheet C by stacking the solar cell encapsulant sheets A and A with the solar cell element B sandwiched therebetween.

FIG. 8 shows one example of production of a flexible solar cell module in the case of using a rectangular solar cell element B.

Specifically, rectangular sheets of the solar cell element B with a predetermined size are prepared instead of the long solar cell element B wound into a roll. As shown in FIG. 8, the long solar cell encapsulant sheets A and A are unrolled such that the adhesive layers face each other, and the solar cell elements B are delivered between the solar cell encapsulant sheets A and A at regular time intervals. Thus, the solar cell encapsulant sheets A and A are stacked with the solar cell elements B sandwiched therebetween to form a laminate sheet C. The laminate sheet C is inserted between a pair of rolls D and D that are heated to a predetermined temperature, and the solar cell encapsulant sheets A and A are adhered to and integrated with each other by heating and pressing the laminate sheet C in the thickness direction so that the solar cell elements B are encapsulated between the solar cell encapsulant sheets A and A. In this manner, solar cell modules F are formed in a continuous manner.

In the production of a flexible solar cell module, the pressing of the laminate sheet C in the thickness direction under heating may be performed at the same time as the formation of the laminate sheet C.

As described above, the solar cell encapsulant sheet of the present invention includes an adhesive layer containing a specific component on a fluoropolymer sheet. Such a structure enables suitable production of flexible solar cell modules in which the solar cell encapsulant sheet is well adhered to a solar cell element by roll-to-roll processing or the like without causing wrinkles and curls.

### Advantageous Effects of Invention

Because of the features described above, the solar cell encapsulant sheet of the present invention makes it possible to suitably produce flexible solar cell modules in which the solar cell encapsulant sheet is well adhered to a solar cell element by encapsulating a solar cell element by roll-to-roll processing in a continuous manner without the need to perform a crosslinking process and without causing wrinkles and curls.

### BRIEF DESCRIPTION OF DRAWINGS

FIG. 1 is a vertical cross-sectional view schematically showing one example of the solar cell encapsulant sheet of the present invention;

FIG. 2 is a vertical cross-sectional view schematically showing one example of a solar cell element;

FIG. 3 is a schematic view showing one example of production of a flexible solar cell module using the solar cell encapsulant sheet of the present invention;

FIG. 4 is a vertical cross-sectional view showing an exemplary flexible solar cell module produced using the solar cell encapsulant sheet of the present invention;

FIG. 5 is a vertical cross-sectional view showing another exemplary flexible solar cell module produced using the solar cell encapsulant sheet of the present invention;

FIG. 6 is a vertical cross-sectional view showing still another exemplary flexible solar cell module produced using the solar cell encapsulant sheet of the present invention;

FIG. 7 is a schematic view showing one example of production of a flexible solar cell module;

FIG. 8 is a schematic view showing another example of production of a flexible solar cell module;

FIG. 9 is a schematic view showing an exemplary peak-valley pattern on the surface of a chill roll in an exemplary device for producing the solar cell encapsulant sheets of the present invention;

FIG. 10 is a schematic view showing an exemplary embossed surface of the solar cell encapsulant sheet of the present invention; and

FIG. 11 is a schematic view showing an exemplary embossing device for the solar cell encapsulant sheets of the present invention.

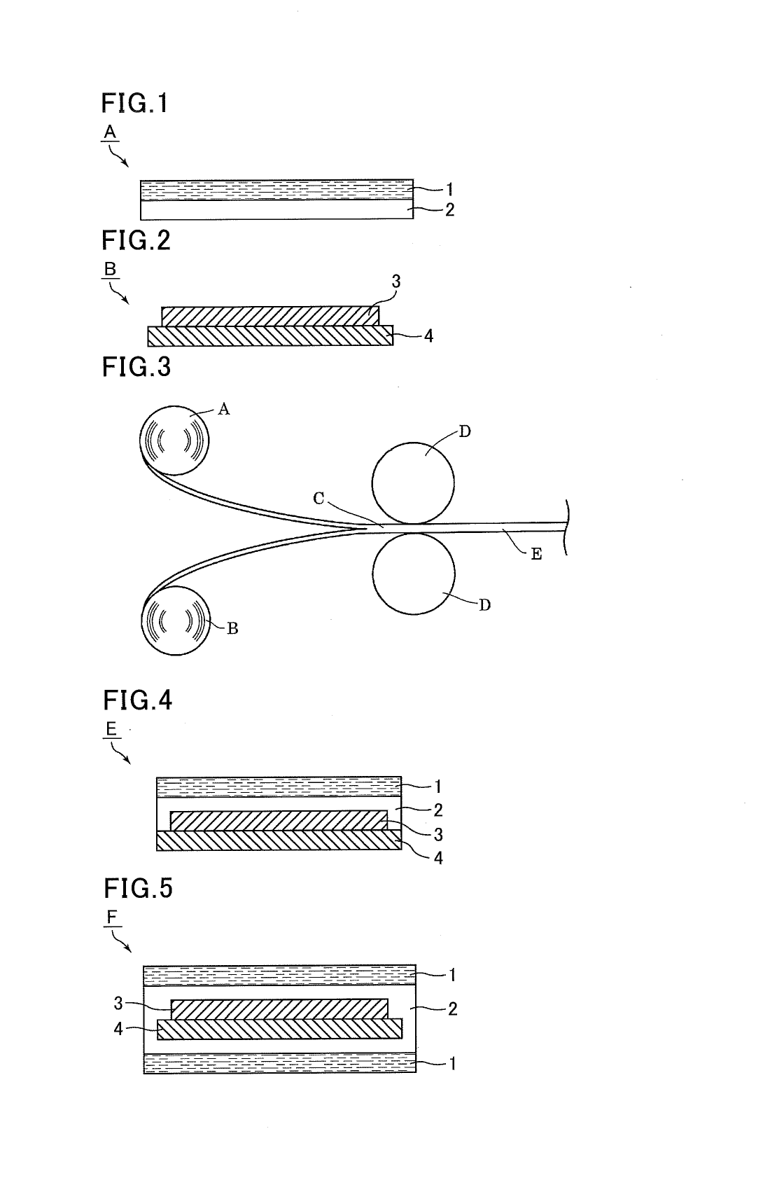

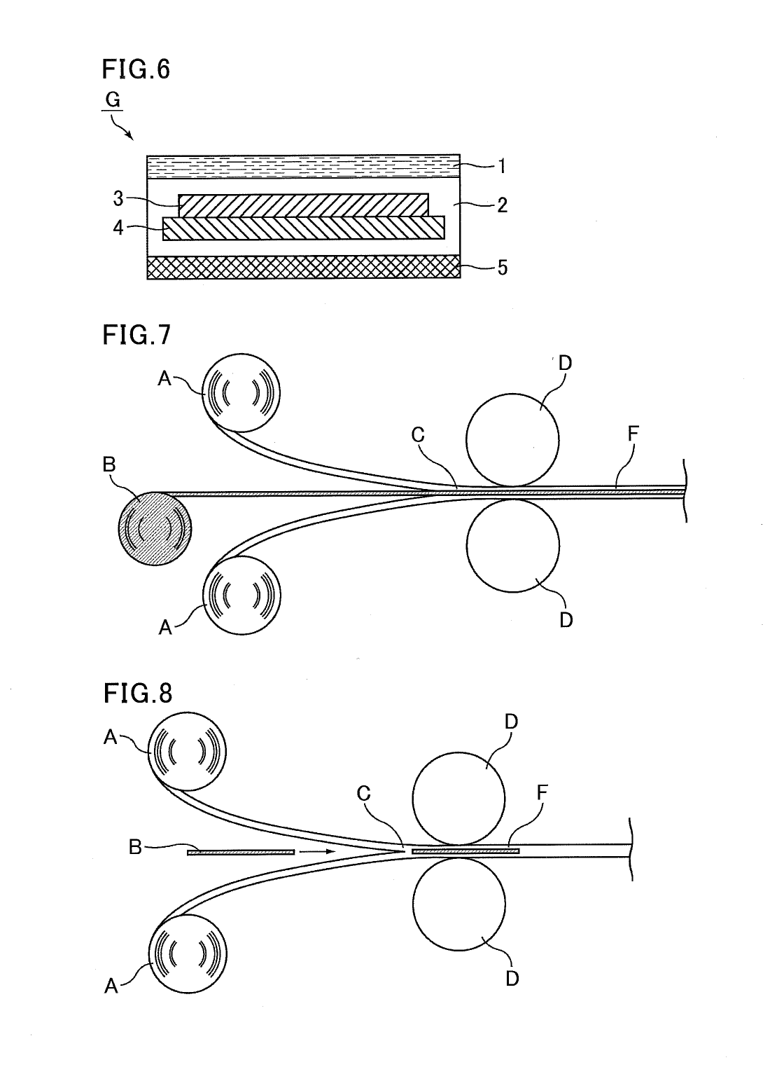

### DESCRIPTION OF EMBODIMENTS

The following examples are offered to illustrate the present invention in more detail, but are not to be construed as limiting the present invention.

### Examples 1 to 21, 23 to 29, and Comparative Examples 4, 6, 7

An adhesive layer composition that contained 100 parts by weight of a modified butene resin in which a butene-ethylene copolymer containing predetermined amounts (shown in Tables 1 to 5) of butene units and ethylene units is graft-modified with maleic anhydride, and a predetermined amount (shown in Tables 1 to 5) of a silane compound selected from 3-glycidoxypropyltrimethoxysilane (trade name: “Z-6040”, available from Dow Corning Toray Co., Ltd.) and 3-acryloxypropyltrimethoxysilane (trade name: “KBM-5103”, available from Shin-Etsu Chemical Co., Ltd.) was molten and kneaded in a first extruder at 250° C.

Separately, a predetermined fluoropolymer shown in Tables 1 to 5 (polyvinylidene fluoride (trade name: “Kynar 720”, available from Arkema); tetrafluoroethylene-ethylene copolymer (trade name: “Neoflon ETFE”, available from Daikin Industries, Ltd.); polyvinyl fluoride resin (trade name: “Tedlar” available from Du Pont); tetrafluoroethylene-perfluoroalkyl vinyl ether copolymer (trade name: “Neoflon PFA”, available from Daikin Industries, Ltd.); ethylene-chlorotrifluoroethylene resin (trade name: “Halar ECTFE” available from Solvay); polychlorotrifluoroethylene resin (trade name: “Neoflon PCTFE”, available from Daikin Industries, Ltd.); a vinylidene fluoride-hexafluoropropylene copolymer (trade name: “Kynar Flex 2800”, available from Arkema); and a mixture of vinylidene fluoride and polymethylmethacrylate (a mixture containing 100 parts by weight of “Kynar 720” (trade name, available from Arkema) and 20 parts by weight of polymethylmethacrylate) was molten and kneaded in a second extruder at an extrusion temperature shown in Tables 1 to 5.

The adhesive layer composition and the fluoropolymer were supplied to a coalescent die connecting the first extruder and the second extruder where they were contacted, and then extruded from a T die connected to the coalescent die into a sheet to produce a long solar cell encapsulant sheet with a predetermined width, which is an integrated laminate having a 0.03 mm-thick fluoropolymer layer on a surface of a 0.3 mm-thick adhesive layer made of the adhesive layer composition.

Tables 1 to 5 show the melt flow rates and the maximum peak temperatures (Tm) determined from endothermic curves obtained by differential scanning calorimetry analysis of the modified butene resins used. Tables 1 to 5 also show the total amounts of maleic anhydride in the modified butene resins.

Subsequently, the solar cell encapsulant sheets obtained above were used to produce flexible solar cell modules in the manner described below. First, as shown in FIG. 8, a rectangular sheet that consisted of a flexible substrate made of a flexible polyimide film and a photoelectric conversion layer made of an amorphous silicon thin film on the flexible substrate was prepared as a solar cell element B, and two rolls of a solar cell encapsulant sheet A obtained above were prepared as solar cell encapsulant sheets A.

Next, as shown in FIG. 8, the rolls of the long solar cell encapsulant sheets A and A were unrolled, and the solar cell element B was delivered between the solar cell encapsulant sheets A and A that were set such that their adhesive layers faced each other. The solar cell encapsulant sheets A and A were stacked with the solar cell element B sandwiched therebetween to form a laminate sheet C. The laminate sheet C was delivered between a pair of rolls D and D heated to a temperature shown in Tables 1 to 5, and pressed in the thickness direction under heating so that the solar cell encapsulant sheets A and A were adhered to and integrated with each other with the solar cell element B encapsulated therebetween. In this manner, a flexible solar cell module F was produced.

### Example 22

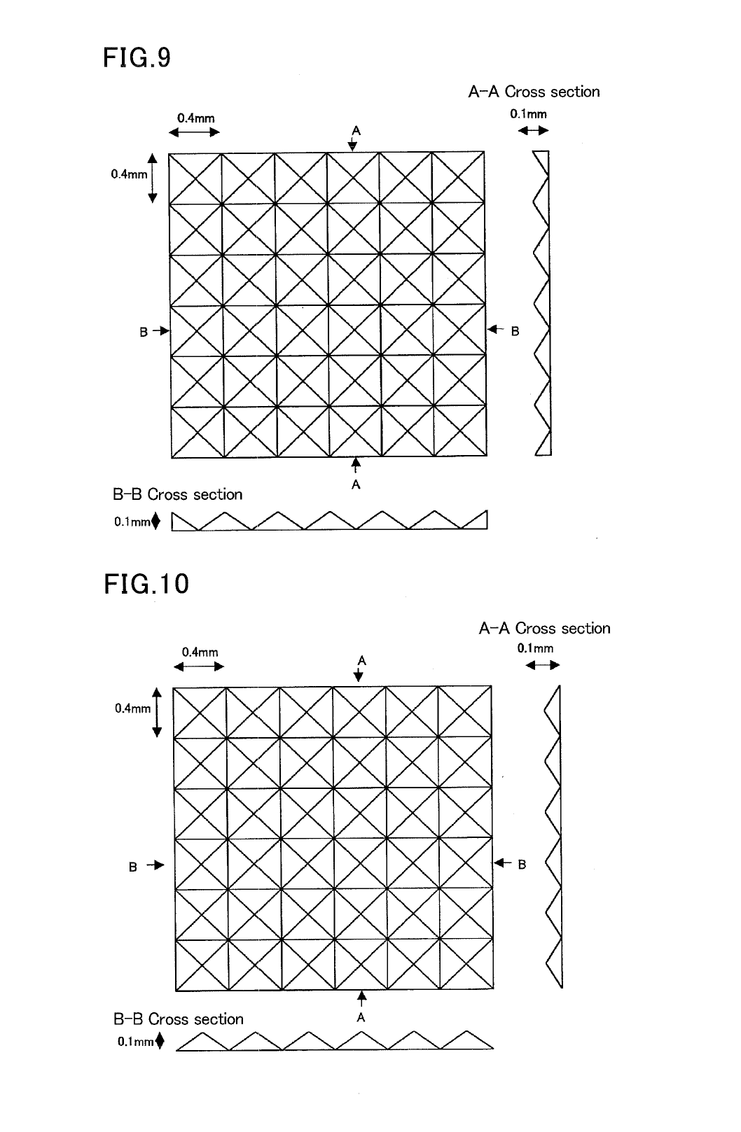

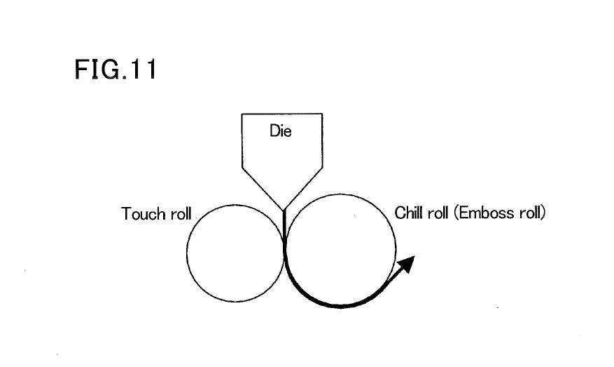

An adhesive layer composition that contained 100 parts by weight of a modified butene resin in which a butene-ethylene copolymer containing predetermined amounts (shown in Table 4) of butene units and ethylene units is graft-modified with maleic anhydride, and a predetermined amount (shown in Table 4) of 3-glycidoxypropyltrimethoxysilane (trade name: “Z-6040”, available from Dow Corning Toray Co., Ltd.) as a silane compound was molten and kneaded in a first extruder at 250° C. Separately, a predetermined fluoropolymer shown in Table 4 (polyvinylidene fluoride, trade name: “Kynar 720”, available from Arkema) was molten and kneaded in a second extruder at an extrusion temperature shown in Table 4. The adhesive layer composition and the fluoropolymer were supplied to a coalescent die connecting the first extruder and the second extruder where they were contacted. Subsequently, when the adhesive layer composition and the fluoropolymer were extruded from a T die connected to the coalescent die into a sheet, a regular pattern of peaks and valleys shown in FIG. 10 was embossed on the surface of the polyvinylidene fluoride sheet using a chill roll with a regular pattern of peaks and valleys as shown in FIG. 9 on the surface. FIG. 11 shows a layout of the embossing roll in a sheet production system. Thus, a solar cell encapsulant sheet was produced, which is a long integrated laminate with a predetermined thickness and consists of a 0.3 mm-thick adhesive layer and a 0.03 mm-thick polyvinylidene fluoride sheet.

Table 4 shows the melt flow rate and the maximum peak temperature (Tm) determined from an endothermic curve obtained by differential scanning calorimetry analysis of the modified butene resin used. Table 4 also shows the total amount of maleic anhydride in the modified butene resin.

A flexible solar cell module was produced in the same manner as in Example 1, except using the above obtained solar cell encapsulant sheet.

Observation of the surface of the obtained flexible solar cell module showed that the regular embossed pattern of peaks and valleys remained as it was.

### Comparative Examples 1, 2

A solar cell encapsulant sheet was obtained to produce a flexible solar cell module in the same manner as in Example 1, except that a low-density polyethylene (Comparative Example 1) or a modified polyethylene obtained by graft modification with maleic anhydride (Comparative Example 2) was used instead of using a modified butene resin, and that a silane compound and a fluoropolymer shown in Table 5 were used.

### Comparative Example 3

A solar cell encapsulant sheet was obtained to produce a flexible solar cell module in the same manner as in Example 1, except that EVA was used instead of using a modified butene resin, and that a silane compound and a fluoropolymer shown in Table 5 were used.

### Comparative Example 5

A solar cell encapsulant sheet was obtained to produce a flexible solar cell module in the same manner as in Example 1, except that polyethylene terephthalate was used instead of using a fluoropolymer, and that a silane compound shown in Table 5 was used.

### Comparative Example 8

A solar cell encapsulant sheet was obtained to produce a flexible solar cell module in the same manner as in Example 1, except using an ethylene-maleic anhydride-ethyl acrylate copolymer (EEAM) produced by radical polymerization of 79.5 parts by weight of ethylene, 20 parts by weight of ethyl acrylate, and 0.5 parts by weight of maleic anhydride instead of using a modified butene resin.

### (Evaluation)

The flexible solar cell modules obtained in the examples and comparative examples were analyzed for the occurrence of wrinkles and curls, peeling strength, and resistance to high-temperature, high-humidity conditions in the following manner. Tables 1 to 5 show the results.

In Comparative Examples 1 to 4, resulting products did not meet the requirements as a solar cell. Accordingly, those products were not evaluated for the resistance to high-temperature, high-humidity conditions and the warpage of the solar cell element.

In Comparative Examples 4 and 5, sufficient adhesive strength was not achieved and the resulting products did not meet the requirements as a solar cell. Accordingly, the test for the resistance to high-temperature, high-humidity conditions was not performed.

### <Occurrence of Wrinkles>

The flexible solar cell modules obtained above were visually evaluated for occurrence of wrinkles and scored based on the following criteria. The ratings of 4 or higher are regarded as being acceptable.

5: No wrinkles were observed.
4: The number of 0.5-mm or shorter wrinkles observed per unit length (m) was 1.
3: The number of 0.5-mm or shorter winkles observed per unit length (m) was 2 to 4.
2: The number of 0.5-mm or shorter winkles observed per unit length (m) was 5 or more.
1: Large wrinkles with a length of 0.5 mm or more were observed.

### <Occurrence of Curls>

A 500 mm×500 mm piece of each flexible solar cell module was placed on a flat surface, and measured for the height of an edge part curling up from the flat surface.

⊚ (Double circle): less than 20 mm
∘ (Circle): 20 mm or more and less than 25 mm
Δ (Triangle): 25 mm or more and less than 35 mm
x (cross): 35 mm or more

### <Peeling Strength>

Each flexible solar cell module obtained above was measured for the peeling strength by peeling the solar cell encapsulant sheet from the solar cell element in accordance with JIS K6854.

### <Resistance to High-Temperature, High-Humidity Conditions (Adhesion)>

Each flexible solar cell module obtained above was left at 85° C. and a relative humidity of 85%, as described in JIC C 8991. The occurrence of peeling of the solar cell encapsulant sheet from the solar cell element was checked every 500 hours after starting the test, and the time when the peeling was observed was recorded.

In the case that the peeling occurred in shorter than 1000 hours, the flexible solar cell module was evaluated as not having sufficient adhesion because flexible solar cell modules are required to have durability of not shorter than 1000 hours as evaluated based on electrical efficiency according to JIC C 8991 which sets the requirements for approval of solar cell modules.

### <Resistance to High-Temperature, High-Humidity Conditions (Electric Power Generation Characteristics)>

Each flexible solar cell module obtained above was left at 85° C. and a relative humidity of 85%, as described in JIC C 8990. Changes in maximum output Pmax were observed with 1116N of Nisshin To a, Inc. The test was not performed for the flexible solar cell modules that had caused peeling in less than 1000 hours. Tables 1 to 5 show the results, and the criteria are shown as follows.

>3000H: 95% of the output value was maintained after 3000 hours.
2000H: 95% of the output value was maintained after 2000 hours.
1000H: 95% of the output value was maintained after 1000 hours (JIS-C8991 standard).
x: 95% of the output value was not maintained after 1000 hours.
-: Measurement was not available because peeling had occurred before 1000 hours.

### <Warpage of Solar Cell Element>

Solar cell encapsulant sheets were produced from the same materials in the same manner as above, except that the thickness of the adhesive layer was changed to 250 μm. Subsequently, both sides of a rectangular solar cell element were laminated with the obtained solar cell encapsulant sheets. The section of the end portion of the solar cell element was observed to measure the thickness of the adhesive layer on the light-receiving surface side (thickness A) and on the back surface side (thickness B). Thereby, the absolute value of (A/B−1) was calculated. The obtained value was recorded according to the following criteria.

⊚ (Double circle): less than 0.1
∘ (Circle): 0.1 or more and less than 0.2
x (Cross): 0.2 or more

TABLE 1

| | | | Example 1 | Example 2 | Example 3 | Example 4 | Example 5 | Example 6 | Example 7 | Example 8 |
|---|---|---|---|---|---|---|---|---|---|---|
| Extrusion temperature | | | 250° C. | 250° C. | 250° C. | 250° C. | 250° C. | 250° C. | 250° C. | 250° C. |
| Fluoropolymer | | | PVDF | PVDF | PVDF | PVDF | PVDF | PVDF | PVDF | PVDF |
| Modified butene | Butene-ethylene | Butene units | 16 | 1 | 20 | 25 | 16 | 16 | 16 | 16 |
| resin | copolymer | (% by weight) | | | | | | | | |
| | | Ethylene units | 84 | 99 | 80 | 75 | 84 | 84 | 84 | 84 |
| | | (% by weight) | | | | | | | | |

| | | | | | | | | |
|---|---|---|---|---|---|---|---|---|
| Total amount of maleic anhydride | 0.3 | 2 | 0.3 | 0.3 | 0.6 | 0.2 | 0.1 | 1.5 |
| (* by weight) | | | | | | | | |
| MFR (g/10 min) | 3 | 2 | 3 | 3 | 5 | 3 | 3 | 7 |
| Tm (° C.) | 85 | 101 | 81 | 80 | 84 | 85 | 85 | 83 |

| | | | | | | | | |
|---|---|---|---|---|---|---|---|---|
| 3-Glycidoxypropyltrimethoxysilane (parts by weight) | 0 | 0.5 | 0.5 | 0.5 | 0.5 | 0.5 | 0.5 | 0.5 |
| 3-Acryloxypropyltrimethoxysilane (parts by weight) | 0 | 0 | 0 | 0 | 0 | 0 | 0 | 0 |
| Roll temperature (° C.) | 90 | 90 | 90 | 90 | 90 | 90 | 90 | 90 |
| Rotation speed (m/min) | 0.5 | 0.5 | 0.5 | 0.5 | 0.5 | 0.5 | 0.5 | 0.5 |
| Wrinkles | 5 | 4 | 5 | 5 | 5 | 5 | 5 | 5 |
| Curls | ◯ | ◯ | ⊚ | ◯ | ⊚ | ⊚ | ⊚ | ⊚ |
| Peeling strength | 25 N/cm | 50 N/cm | 70 N/cm | 62 N/cm | 70 N/cm | 50 N/cm | 25 N/cm | 78 N/cm |
| | | or more | or more | or more | or more | or more | or more | or more |
| Resistance to high-temperature and high-humidity | 1500 H | 3000 H | 3000 H | 3000 H | 3000 H | 3000 H | 2000 H | 3000 H |
| (adhesion) | | or longer | or longer | or longer | or longer | or longer | | or longer |
| Resistance to high-temperature and high-humidity | 1000 H | >3000 H | >3000 H | >3000 H | >3000 H | >3000 H | 1000 H | 2000 H |
| (electric power generation characteristics) | | | | | | | | |
| Warpage of solar cell element | ◯ | ⊚ | ⊚ | ⊚ | ⊚ | ⊚ | ⊚ | ⊚ |

TABLE 2

| | | | Example 9 | Example 10 | Example 11 | Example 12 | Example 13 |
|---|---|---|---|---|---|---|---|
| Extrusion temperature | | | 250° C. | 250° C. | 250° C. | 250° C. | 250° C. |
| Fluoropolymer | | | PVDF | PVDF | PVDF | PVDF | PVDF |
| Modified butene | Butene-ethylene | Butene units | 16 | 16 | 16 | 16 | 16 |
| resin | copolymer | (% by weight) | | | | | |
| | | Ethylene units | 84 | 84 | 84 | 84 | 84 |
| | | (% by weight) | | | | | |

| | | | | | |
|---|---|---|---|---|---|
| Total amount of maleic anhydride | 1.5 | 1.5 | 1.5 | 1.5 | 1.5 |
| (% by weight) | | | | | |
| MFR (g/10 min) | 7 | 7 | 7 | 7 | 7 |
| Tm (° C.) | 83 | 83 | 83 | 83 | 83 |

| | | | | | |
|---|---|---|---|---|---|
| 3-Glycidoxypropyltrimethoxysilane (parts by weight) | 0.05 | 1.5 | 2 | 5 | 7 |
| 3-Acryloxypropyltrimethoxysilane (parts by weight) | 0 | 0 | 0 | 0 | 0 |
| Roll temperature (° C.) | 90 | 90 | 90 | 90 | 90 |
| Rotation speed (m/min) | 0.5 | 0.5 | 0.5 | 0.5 | 0.5 |
| Wrinkles | 5 | 5 | 5 | 4 | 3 |
| Curls | ◯ | ⊚ | ◯ | ◯ | Δ |
| Peeling strength | 25 N/cm | 78 N/cm | 78 N/cm | 78 N/cm | 78 N/cm |
| | | or more | or more | or more | or more |
| Resistance to high-temperature and high-humidity | 1500 H | 3000 H | 3000 H | 3000 H | 3000 H |
| (adhesion) | | or longer | or longer | or longer | or longer |
| Resistance to high-temperature and high-humidity | 1000 H | >3000 H | >3000 H | >3000 H | >3000 H |
| (electric power generation characteristics) | | | | | |
| Warpage of solar cell element | ◯ | ⊚ | ⊚ | ⊚ | ⊚ |

TABLE 3

| | | | Example | Example | Example | Example | Example | Example | Example | Example |
|---|---|---|---|---|---|---|---|---|---|---|
| | | | 14 | 15 | 16 | 17 | 18 | 19 | 20 | 21 |
| Extrusion temperature | | | 250° C. | 250° C. | 250° C. | 290° C. | 290° C. | 250° C. | 290° C. | 290° C. |
| Fluoropolymer | | | PVDF | PVDF | PVDF | ETFE | ETFE | PVF | FAP | ECTFE |
| Modified butene | Butene-ethylene | Butene units | 16 | 16 | 10 | 16 | 16 | 16 | 16 | 16 |
| resin | copolymer | (% by weight) | | | | | | | | |
| | | Ethylene units | 84 | 84 | 90 | 84 | 84 | 84 | 84 | 84 |
| | | (% by weight) | | | | | | | | |

| | | | | | | | | |
|---|---|---|---|---|---|---|---|---|
| Total amount of maleic anhydride | 3 | 0.9 | 0.3 | 0.3 | 0.3 | 0.3 | 0.3 | 0.3 |
| (% by weight) | | | | | | | | |
| MFR (g/10 min) | 9 | 8 | 4 | 3 | 3 | 3 | 3 | 3 |
| Tm (° C.) | 81 | 84 | 90 | 85 | 85 | 85 | 85 | 85 |

| | | | | | | | | |
|---|---|---|---|---|---|---|---|---|
| 3-Glycidoxypropyltrimethoxysilane (parts by weight) | 0.5 | 0.5 | 0.5 | 0 | 0 | 0.5 | 0.5 | 0.5 |
| 3-Acryloxypropyltrimethoxysilane (parts by weight) | 0 | 0 | 0 | 0.6 | 0 | 0 | 0 | 0 |
| Roll temperature (° C.) | 90 | 90 | 90 | 90 | 90 | 90 | 90 | 90 |
| Rotation speed (m/min) | 0.5 | 0.5 | 0.5 | 0.5 | 0.5 | 0.5 | 0.5 | 0.5 |
| Wrinkles | 4 | 5 | 5 | 5 | 5 | 5 | 5 | 5 |
| Curls | ⊚ | ⊚ | ⊚ | ⊚ | ◯ | ⊚ | ⊚ | ⊚ |
| Peeling strength | 78 N/cm | 78 N/cm | 50 N/cm | 25 N/cm | 25 N/cm | 70 N/cm | 50 N/cm | 50 N/cm |
| | or more | or more | or more | | | or more | or more | or more |
| Resistance to high-temperature and high-humidity | 3000 H | 3000 H | 3000 H | 1500 H | 1500 H | 3000 H | 3000 H | 3000 H |
| (adhesion) | or longer | or longer | or longer | | | or longer | or longer | or longer |
| Resistance to high-temperature and high-humidity | 1000 H | >3000 H | >3000 H | 1000 H | 1000 H | >3000 H | >3000 H | >3000 H |
| (electric power generation characteristics) | | | | | | | | |
| Warpage of solar cell element | ⊚ | ⊚ | ⊚ | ◯ | ◯ | ⊚ | ⊚ | ⊚ |

TABLE 4

| | | | Example | Example | Example | Example | Example | Example | Example | Example |
|---|---|---|---|---|---|---|---|---|---|---|
| | | | 22 | 23 | 24 | 25 | 26 | 27 | 28 | 29 |
| Extrusion temperature | | | 260° C. | 300° C. | 250° C. | 250° C. | 250° C. | 250° C. | 250° C. | 230° C. |
| Fluoropolymer | | | PCTFE | ETFE | PVF | PVDF | PVDF | PVDF | PVDF- | PVDF/ |
| | | | | | | | | | HFP | PMMA |
| Modified butene | Butene-ethylene | Butene units | 16 | 16 | 16 | 16 | 16 | 16 | 16 | 16 |
| resin | copolymer | (% by weight) | | | | | | | | |
| | | Ethylene units | 84 | 84 | 84 | 84 | 84 | 84 | 84 | 84 |
| | | (% by weight) | | | | | | | | |

| | | | | | | | | |
|---|---|---|---|---|---|---|---|---|
| Total amount of maleic anhydride | 0.3 | 0.3 | 0.6 | 0.2 | 0.9 | 0.3 | 0.3 | 0.3 |
| (% by weight) | | | | | | | | |
| MFR (g/10 min) | 3 | 3 | 5 | 3 | 8 | 3 | 3 | 3 |
| Tm (° C.) | 85 | 85 | 85 | 85 | 84 | 85 | 85 | 85 |

| | | | | | | | | |
|---|---|---|---|---|---|---|---|---|
| 3-Glycidoxypropyltrimethoxysilane (parts by weight) | 0.5 | 0 | 0.5 | 0.5 | 0.5 | 0.5 | 0.5 | 0.5 |
| 3-Acryloxypropyltrimethoxysilane (parts by weight) | 0 | 0 | 0 | 0 | 0 | 0 | 0 | 0 |
| Roll temperature (° C.) | 90 | 97 | 98 | 90 | 90 | 90 | 90 | 90 |
| Rotation speed (m/min) | 0.5 | 2.5 | 4 | 0.5 | 0.5 | 0.5 | 0.5 | 0.5 |
| Wrinkles | 5 | 5 | 5 | 5 | 5 | 5 | 5 | 5 |
| Curls | ⊚ | ◯ | ◯ | ◯ | ◯ | ⊚ | ⊚ | ⊚ |
| Peeling strength | 50 N/cm | 50 N/cm | 70 N/cm | 70 N/cm | 70 N/cm | 50 N/cm | 50 N/cm | 50 N/cm |
| | or more | or more | or more | or more | or more | or more | or more | or more |
| Resistance to high-temperature and high-humidity | 3000 H | 1500 H | 3000 H | 3000 H | 3000 H | 3000 H | 3000 H | 3000 H |
| (adhesion) | or longer | | or longer | or longer | or longer | or longer | or longer | or longer |
| Resistance to high-temperature and high-humidity | >3000 H | 1000 H | >3000 H | >3000 H | >3000 H | >3000 H | >3000 H | >3000 H |
| (electric power generation characteristics) | | | | | | | | |
| Warpage of solar cell element | ⊚ | ◯ | ⊚ | ⊚ | ◯ | ⊚ | ⊚ | ⊚ |

TABLE 5

| | | | Compar- | Compar- | Compar- | Compar- | Compar- | Compar- | Compar- | Compar- |
|---|---|---|---|---|---|---|---|---|---|---|
| | | | ative | ative | ative | ative | ative | ative | ative | ative |
| | | | Example 1 | Example 2 | Example 3 | Example 4 | Example 5 | Example 6 | Example 7 | Example 8 |
| Extrusion temperature | | | 290° C. | 290° C. | 290° C. | 250° C. | — | 250° C. | 250° C. | 250° C. |
| Fluoropolymer | | | ETFE | ETFE | ETFE | PVF | PET | PVDF | PVDF | PVDF |
| Modified butene | Butene-ethylene | Butene units | 0 | 0 | EVA (VA | 16 | 16 | 16 | 50 | EEAM |
| resin | copolymer | (% by weight) | | | content: | | | | | |
| | | Ethylene units | 100 | 100 | 28%) | 84 | 84 | 84 | 50 | |
| | | (% by weight) | | | | | | | | |

| | | | | | | | | |
|---|---|---|---|---|---|---|---|---|
| Total amount of maleic anhydride | 0 | 0.01 | | 0.01 | 0.3 | 5 | 0.3 | 0.5 |
| (% by weight) | | | | | | | | |
| MFR (g/10 min) | 2.5 | 0.5 | 30 | 3 | 3 | 9 | 4.8 | 20 |
| Tm (° C.) | 115 | 120 | 67 | 85 | 85 | 78 | 66 | 80 |

| | | | | | | | | |
|---|---|---|---|---|---|---|---|---|
| 3-Glycidoxypropyltrimethoxysilane (parts by weight) | 0.5 | 0.5 | 0.5 | 0.5 | 0.5 | 0.5 | 0.5 | 0.5 |
| 3-Acryloxypropyltrimethoxysilane (parts by weight) | 0 | 0 | 0 | 0 | 0 | 0 | 0 | 0 |
| Roll temperature (° C.) | 135 | 135 | 90 | 90 | 97 | 90 | 90 | 90 |
| Rotation speed (m/min) | 0.5 | 0.5 | 0.5 | 0.5 | 0.5 | 0.5 | 0.5 | 0.5 |
| Wrinkles | 2 | 1 | Pores | Pores | 5 | 3 | 3 | 5 |
| | | | created | created | | | | |
| | | | by | by | | | | |
| | | | foaming | foaming | | | | |
| Curls | X | X | X | ◯ | ◯ | ◯ | Δ | ◯ |
| Peeling strength | Already | Already | Already | less than | less than | 70 N/cm | 70 N/cm | 30 N/cm |
| | separated | separated | separated | 10 N/cm | 5 N/cm | or more | or more | or more |
| Resistance to high-temperature and high-humidity | — | — | — | — | — | 2000 H | 1000 H | X |
| (adhesion) | | | | | | | | |
| Resistance to high-temperature and high-humidity | — | — | — | — | — | X | — | X |
| (electric power generation characteristics) | | | | | | | | |
| Warpage of solar cell element | — | — | — | X | ◯ | ◯ | X | X |

### Examples 30 to 34

A flexible solar cell module was produced in the same manner as in Example 1, except using an adhesive layer composition consisting of: 100 parts by weight of a modified butene resin in which a butene-ethylene copolymer including butene units and ethylene units in amounts shown in Table 6 is graft-modified with maleic anhydride; and, as a silane compound, an amount shown in Table 6 of 3-glycidoxypropyltrimethoxysilane (trade name: “Z-6040”, available from Dow Corning Toray Co., Ltd.), 2-(3,4-epoxycyclohexyl)ethyltrimethoxysilane (trade name: “Z-6043”, available from Dow Corning Toray Co., Ltd.), 3-glycidoxypropyltriethoxysilane (trade name: “KBE-403”, available from Shin-Etsu Chemical Co., Ltd.), 3-glycidoxypropylmethyldimethoxysilane (trade name: “KBM-402”, available from Shin-Etsu Chemical Co., Ltd.), or 3-glycidoxypropylmethyltriethoxysilane (trade name: “KBE-402”, available from Shin-Etsu Chemical Co., Ltd.). The obtained flexible solar cell module was evaluated for each item. Table 6 shows the results.

TABLE 6

| | | | Example 30 | Example 31 | Example 32 | Example 33 | Example 34 |
|---|---|---|---|---|---|---|---|
| Extrusion temperature | | | 250° C. | 250° C. | 250° C. | 250° C. | 250° C. |
| Fluoropolymer | | | PVDF | PVDF | PVDF | PVDF | PVDF |
| Modified butene | Butene-ethylene | Butene units | 16 | 16 | 16 | 16 | 16 |
| resin | copolymer | (% by weight) | | | | | |
| | | Ethylene units | 84 | 84 | 84 | 84 | 84 |
| | | (% by weight) | | | | | |

| | | | | | |
|---|---|---|---|---|---|
| Total amount of maleic anhydride | 0.3 | 0.3 | 0.3 | 0.3 | 0.3 |
| (% by weight) | | | | | |
| MFR (g/10 min) | 3 | 3 | 3 | 3 | 3 |
| Tm (° C.) | 85 | 85 | 85 | 85 | 85 |

| | | | | | |
|---|---|---|---|---|---|
| 3-Glycidoxypropyltrimethoxysilane (parts by weight) | 0.3 | — | — | — | — |
| 2-(3,4-Epoxy cyclohexyl)ethyl trimethoxysilane (parts by weight) | — | 0.3 | — | — | — |
| 3-Glycidoxypropyl triethoxysilane (parts by weight) | — | — | 0.3 | — | — |
| 3-Glycidoxypropyl methyl dimethoxysilane (parts by weight) | — | — | — | 0.3 | — |
| 3-Glycidoxypropyl methyl diethoxysilane (parts by weight) | — | — | — | — | 0.3 |
| Roll temperature (° C.) | 90 | 90 | 90 | 90 | 90 |
| Rotation speed (m/min) | 0.5 | 0.5 | 0.5 | 0.5 | 0.5 |
| Wrinkles | 5 | 5 | 5 | 5 | 5 |
| Curls | ⊚ | ⊚ | ⊚ | ⊚ | ⊚ |
| Peeling strength | 50 N/cm | 50 N/cm | 50 N/cm | 50 N/cm | 50 N/cm |
| | or more | or more | or more | or more | or more |
| Resistance to high-temperature and high-humidity | 3000 H | 3000 H | 3000 H | 3000 H | 3000 H |
| (adhesion) | or longer | or longer | or longer | or longer | or longer |
| Resistance to high-temperature and high-humidity | >3000 H | >3000 H | >3000 H | >3000 H | >3000 H |
| (electric power generation characteristics) | | | | | |
| Warpage of solar cell element | ⊚ | ⊚ | ⊚ | ⊚ | ⊚ |

### Examples 35 to 39, Comparative Examples 9 to 11

A flexible solar cell module was produced in the same manner as in Example 1, except using an adhesive layer composition consisting of: 100 parts by weight of a modified α-olefin resin in which an α-olefin-ethylene copolymer that contains α-olefin units and ethylene units in amounts shown in Table 7 is graft-modified with maleic anhydride; and, as a silane compound, an amount shown in Table 7 of 3-glycidoxypropyltrimethoxysilane (trade name: “Z-6040”, available from Dow Corning Toray Co., Ltd.). The obtained flexible solar cell module was evaluated for each item. Table 7 shows the results.

TABLE 7

| | | | | | | | | | Compar- | Compar- | Compar- |
|---|---|---|---|---|---|---|---|---|---|---|---|
| | | | | | | | | | ative | ative | ative |
| | | | | Exam- | Exam- | Exam- | Exam- | Exam- | Exam- | Exam- | Exam- |
| | | | | ple 35 | ple 36 | ple 37 | ple 38 | ple 39 | ple 9 | ple 10 | ple 11 |
| Extrusion temperature | | | | 250° C. | 250° C. | 250° C. | 250° C. | 250° C. | 250° C. | 250° C. | 250° C. |
| Fluoropolymer | | | | PVDF | PVDF | PVDF | PVDF | PVDF | PVDF | PVDF | PVDF |
| Modified | α-olefin- | α-olefin | 1-butene | 20 | — | — | — | — | 30 | — | — |
| α-olefin | ethylene | units | 1-hexene | — | 10 | 20 | — | — | — | 30 | — |
| resin | copolymer | (% by weight) | 1-octene | — | — | — | 15 | 20 | — | — | 30 |

| | | | | | | | | |
|---|---|---|---|---|---|---|---|---|
| ethylene units (% by weight) | 80 | 100 | 100 | 100 | 100 | 100 | 100 | 100 |

| | | | | | | | | |
|---|---|---|---|---|---|---|---|---|
| Total amount of maleic anhydride | 0.3 | 2 | 0.3 | 0.3 | 0.6 | 0.2 | 0.1 | 1.5 |
| (% by weight) | | | | | | | | |
| MFR (g/10 min) | 3 | 2 | 3 | 3 | 5 | 3 | 3 | 7 |
| Tm (° C.) | 80 | 101 | 86 | 98 | 87 | 70 | 75 | 72 |

| | | | | | | | | |
|---|---|---|---|---|---|---|---|---|
| 3-Glycidoxypropyltrimethoxysilane (parts by weight) | 0 | 0.5 | 0.5 | 0.5 | 0.5 | 0.5 | 0.5 | 0.5 |
| Roll temperature (° C.) | 90 | 90 | 90 | 90 | 90 | 90 | 90 | 90 |
| Rotation speed (m/min) | 0.5 | 0.5 | 0.5 | 0.5 | 0.5 | 0.5 | 0.5 | 0.5 |
| Wrinkles | 5 | 4 | 5 | 5 | 5 | 5 | 5 | 5 |
| Curls | ◯ | ◯ | ⊚ | ◯ | ⊚ | ⊚ | ⊚ | ⊚ |
| Peeling strength | 25 N/cm | 50 N/cm | 70 N/cm | 62 N/cm | 70 N/cm | 50 N/cm | 50 N/cm | 50 N/cm |
| | | or more | or more | or more | or more | or more | or more | or more |
| Resistance to high-temperature and high-humidity | 1500 H | 3000 H | 3000 H | 3000 H | 3000 H | 1000 H | 1000 H | 1000 H |
| (adhesion) | | or longer | or longer | or longer | or longer | | | |
| Resistance to high-temperature and high-humidity | 1000 H | >3000 H | >3000 H | >3000 H | >3000 H | — | — | — |
| (electric power generation characteristics) | | | | | | | | |
| Warpage of solar cell element | ◯ | ⊚ | ⊚ | ⊚ | ⊚ | X | X | X |

### Examples 40, 41

A flexible solar cell module was produced in the same manner as in Example 1, except using an adhesive layer composition consisting of: 90 parts by weight of a modified butene resin in which a butene-ethylene copolymer containing butene units and ethylene units in amounts shown in Table 8 is graft-modified with maleic anhydride; 10 parts by weight of a low-density polyethylene (trade name: “L1780”, available from Asahi Kasei Chemicals Corporation) or a linear low-density polyethylene copolymer (produced by ethylene-1-butene copolymerization of 84% by weight of ethylene and 16% by weight of 1-butene); and, as a silane compound, 0.5 parts by weight of 3-glycidoxypropyltrimethoxysilane (trade name: “Z-6040”, available from Dow Corning Toray Co., Ltd.). The obtained flexible solar cell module was evaluated for each item. Table 8 shows the results.

TABLE 8

| | | Example 40 | Example 41 |
|---|---|---|---|
| Extrusion temperature | | 250° C. | 250° C. |
| Fluoropolymer | | PVDF | PVDF |
| Maleic | Amount (parts by weight) | 90 | 90 |
| anhydride-modified | Buten units (% by weight) | 16 | 16 |
| butene-ethylene | Ethylene units (% by weight) | 84 | 84 |
| copolymer | Total amount of maleic anhydride | 0.3 | 0.3 |
| | (% by weight) | | |
| | MFR (g/10 min) | 3 | 3 |
| | Tm (° C.) | 85 | 85 |
| Low-density | Low-density polyethylene | 10 | — |
| polyethylene | Linear low-density | — | 10 |
| | polyethylene copolymer | | |

| | | |
|---|---|---|
| 3-glycidoxypropyl trimethoxysilane (parts by weight) | 0.5 | 0.5 |
| Roll temperature (° C.) | 90 | 90 |
| Rotation speed (m/min) | 0.5 | 0.5 |
| Wrinkles | 5 | 4 |
| Curls | ⊚ | ⊚ |
| Peeling strength | 50N/cm or more | 50N/cm or more |
| Resistance to high-temperature and high-humidity | 3000 H or longer | 3000 H or longer |
| (adhesion) | | |
| Resistance to high-temperature and high-humidity | >3000 H | >3000 H |
| (electric power generation characteristics) | | |
| Warpage of solar cell element | ⊚ | ⊚ |

### INDUSTRIAL APPLICABILITY

The solar cell encapsulant sheet of the present invention makes it possible to suitably produce flexible solar cell modules in which the solar cell encapsulant sheet is well adhered to a solar cell element by roll-to-roll processing without causing wrinkles and curls.

### REFERENCE SIGNS LIST

A Solar cell encapsulant sheet
B Solar cell element
C Laminate sheet
D Roll
E, F, G Flexible solar cell module
1 Fluoropolymer sheet
2 Adhesive layer
3 Photoelectric conversion layer
4 Flexible substrate
5 Metal plate

1. A solar cell encapsulant sheet comprising
a fluoropolymer sheet and
an adhesive layer that comprises a maleic anhydride-modified olefin resin on the fluoropolymer sheet,
the maleic anhydride-modified olefin resin being a resin in which an α-olefin-ethylene copolymer that includes 1 to 25% by weight of α-olefin units is graft-modified with maleic anhydride, and
a total amount of maleic anhydride being 0.1 to 3% by weight.

2. The solar cell encapsulant sheet according to claim 1,
wherein the α-olefin is butene and/or octene.

3. The solar cell encapsulant sheet according to claim 1,
wherein the adhesive layer further contains a silane compound represented by the formula (I) in an amount of 0.05 to 5 parts by weight relative to 100 parts by weight of the maleic anhydride-modified olefin resin,
the formula (I) being: 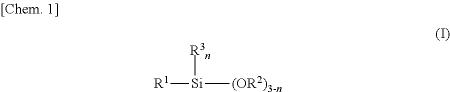
wherein R¹ represents 3-glycidoxypropyl or 2-(3,4-epoxy cyclohexyl)ethyl; R² represents an alkyl group containing 1 to 3 carbon atoms; R³ represents an alkyl group containing 1 to 3 carbon atoms; and n is 0 or 1.

4. The solar cell encapsulant sheet according to claim 1,
wherein the fluoropolymer sheet comprises at least one fluoropolymer selected from the group consisting of a tetrafluoroethylene-ethylene copolymer, an ethylene-chlorotrifluoroethylene resin, a polychlorotrifluoroethylene resin, a polyvinylidene fluoride resin, a tetrafluoroethylene-perfluoroalkyl vinyl ether copolymer, a polyvinyl fluoride resin, a tetrafluoroethylene-hexafluoropropylene copolymer, a vinylidene fluoride-hexafluoropropylene copolymer, and a mixture of polyvinylidene fluoride and polymethylmethacrylate.

5. A flexible solar cell module comprising
a solar cell encapsulant sheet according to claim 1, and
a solar cell element that comprises a flexible substrate and a photoelectric conversion layer on the flexible substrate,
the solar cell encapsulant sheet and the solar cell element being integrally laminated.

6. A flexible solar cell module comprising
a first solar cell encapsulant sheet being a solar cell encapsulant sheet according to claim 1,
a solar cell element that comprises a flexible substrate and a photoelectric conversion layer on the flexible substrate, and
a second solar cell encapsulant sheet being a solar cell encapsulant sheet according to claim 1,
the first solar cell encapsulant sheet, the solar cell element, and the second solar cell encapsulant sheet being integrally laminated in the described order.

7. A flexible solar cell module comprising
a solar cell encapsulant sheet according to claim 1,
a solar cell element that comprises a flexible substrate and a photoelectric conversion layer on the flexible substrate,
an adhesive layer that comprises a maleic anhydride-modified olefin resin, and
a metal plate,
the solar cell encapsulant sheet, the solar cell element, the adhesive layer, and the metal plate being integrally laminated in the described order.

8. A method for producing a solar cell encapsulant sheet comprising forming an adhesive layer by
charging an extruder with the following components:
100 parts by weight of a maleic anhydride-modified olefin resin, the maleic anhydride-modified olefin resin being a resin in which an α-olefin-ethylene copolymer that includes 1 to 25% by weight of α-olefin units is graft-modified with maleic anhydride, and a total amount of maleic anhydride being 0.1 to 3% by weight; and
0.05 to 5 parts by weight of a silane compound represented by the formula (I): 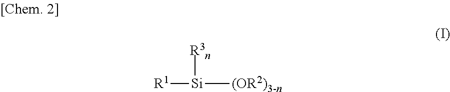
wherein R¹ represents 3-glycidoxypropyl or 2-(3,4-epoxy cyclohexyl)ethyl; R² represents an alkyl group containing 1 to 3 carbon atoms; R³ represents an alkyl group containing 1 to 3 carbon atoms; and n is 0 or 1,
and melt-kneading and extruding the components from the extruder to form an adhesive layer in a sheet form.
